(19) United States
(12) Patent Application Publication
(10) Pub. No.: US 2026/0206502 A1
(43) Pub. Date: Jul. 16, 2026

(54) PULSE ALD SEQUENCE FOR LOW FLUORINE WN DEPOSITION

(71) Applicant: Lam Research Corporation, Fremont, CA (US)

(72) Inventors: Zhongbo Yan, Castro Valley, CA (US); Ashwin Agathya Boochakravarthy, San Jose, CA (US); Xiaolan Ba, Fremont, CA (US); Juwen Gao, San Jose, CA (US); Ravi Bharatkumar Parmar, San Jose, CA (US); Sai Rachakonda, Union City, CA (US)

(21) Appl. No.: 19/128,000

(22) PCT Filed: Nov. 8, 2023
(86) PCT No.: PCT/US2023/079163

§ 371 Date: May 7, 2025

Related U.S. Application Data
(60) Provisional application No. 63/383,162, filed on Nov. 10, 2022.
(60) Provisional application No. 63/499,159, filed on Apr. 28, 2023.

(51) Int. Cl. H10P 14/43; C23C 16/02; C23C 16/44; C23C 16/455; C23C 16/52; H10P 14/40; H10W 20/00

(52) U.S. Cl. CPC H10P 14/43; C23C 16/0281; C23C 16/4408; C23C 16/45534; C23C 16/45553; C23C 16/45565; C23C 16/52; H10P 14/418; H10W 20/033

(57) ABSTRACT

Provided herein are methods of forming tungsten nitride (WN) barrier layers in features, the method comprises forming a tungsten sublayer by dosing diborane to a chamber and purging diborane from the chamber one or more times, and after dosing and purging diborane, dosing tungsten hexafluoride to the chamber and purging tungsten hexafluoride from the chamber multiple times; after forming the tungsten sublayer, dosing diborane to the chamber and purging diborane from the chamber; and after dosing and purging diborane, dosing a nitriding agent to the chamber to convert the tungsten sublayer to a tungsten nitride sublayer and purging the nitriding agent from the chamber.

### RELATED APPLICATION(S)

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

Deposition of materials including tungsten-containing materials is an integral part of many semiconductor fabrication processes. These materials may be used for horizontal interconnects, vias between adjacent metal layers, and contacts between metal layers and devices. As devices shrink and more complex patterning schemes are utilized in the industry, deposition of tungsten films becomes a challenge. The continued decrease in feature size and film thickness bring various challenges including high resistivity for thinner films and difficulty in obtaining void-free fill in features. Deposition in complex high aspect ratio structures such as 3D NAND structures is particularly challenging.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided herein are methods of forming tungsten nitride (WN) barrier layers in features. The methods include atomic layer deposition (ALD) pulse sequences using tungsten hexafluoride (WF₆) as a reactant that result in low fluorine concentration in the deposited WN barrier layers. The methods also include methods of loading wafers into a multi-station tool to reduce non-uniformities of tungsten-containing layers between stations.

One aspect of the disclosure relates to a method including providing a 3-D structure of a partially manufactured semiconductor substrate to a chamber, the 3-D structure including sidewalls, a plurality of openings in the sidewalls leading to a plurality of features having a plurality of interior regions fluidically accessible through the openings; depositing a tungsten nitride film in the plurality of features using one or more deposition cycles, each deposition cycle including (a)-(c):
(a) forming a tungsten sublayer by:
   i) dosing diborane to the chamber and purging diborane from the chamber one or more times;
   ii) after (i), dosing tungsten hexafluoride to the chamber and purging tungsten hexafluoride from the chamber multiple times;
(b) after (a), dosing diborane to the chamber and purging diborane from the chamber; and
(c) after (b), dosing a nitriding agent to the chamber to convert the tungsten sublayer to a tungsten nitride sublayer and purging the nitriding agent from the chamber.

In some embodiments, the nitriding agent is ammonia. In some embodiments, the tungsten nitride film is deposited on an aluminum oxide film in the plurality of features. In some embodiments, 2, 3, or 4 deposition cycles are used to deposit the tungsten nitride film having a thickness of 10 to 20 Å.

In some embodiments, each deposition cycle includes two or more iterations of (i) before the first iteration of (ii) in the deposition cycle. In some embodiments, each deposition cycle includes at least 3 iterations of (ii). In some embodiments, each deposition cycle includes at least 3 iterations of (ii) In some embodiments, each deposition cycle includes at least 5 iterations of (ii).

In some embodiments, each of (b) and (c) is performed only once per deposition cycle. In some embodiments, the number of iterations of (ii) in each deposition cycle is greater than the number of iterations of (i). In some embodiments, each dose in (i) has a duration of between 1 and 2 seconds. In some embodiments, each purge in (i) has a duration of less than 5 seconds. In some embodiments, each dose in (ii) has a duration of less than 1 second. In some such embodiments, each purge in (ii) has a duration of between 1 and 2 seconds. In some embodiments, a duration of the dose in (b) is 2 to 10 times longer than a duration of each dose in (i). In some embodiments, the total volume of B₂H₆ to WF₆ in (a) is at least 2:1.

In some embodiments, the concentration of fluorine (F) in the tungsten nitride film is less than 1.0E21. In some embodiments, the concentration of fluorine (F) in the tungsten nitride film is less than 1.0E20. In some embodiments, the concentration of fluorine (F) in the tungsten nitride film is less than 1.0E19. In some embodiments, the concentration of fluorine (F) in the tungsten nitride film is less than 5E18.

In some embodiments, the method further includes, after depositing the tungsten nitride film, filling the plurality of features with metal.

Another aspect of the disclosure relates to an apparatus including a process chamber including one or more showerheads in the process chamber to direct gases and one or more substrate supports;
a controller configured to execute machine-readable instructions for depositing a tungsten nitride film using one or more deposition cycles, each deposition cycle including (a)-(c):
(a) causing formation of a tungsten sublayer by:
   i) causing dosing of diborane to the process chamber and purging diborane from the process chamber one or more times;
   ii) after (i), causing dosing of tungsten hexafluoride to the process chamber and purging tungsten hexafluoride from the process chamber multiple times;
(b) after (a), causing dosing of diborane to the process chamber and purging diborane from the process chamber; and
(c) after (b), causing dosing of a nitriding agent to the process chamber to convert the tungsten sublayer to a tungsten nitride sublayer and purging the nitriding agent from the process chamber.

In another aspect of the embodiments herein, a method of depositing a tungsten-containing layer is provided, the method including: providing a process chamber including a plurality of stations; indexing each substrate of a plurality of substrates to a corresponding station of the plurality of stations; after indexing all of the plurality of substrates to the corresponding stations, reducing pressure in the process chamber below a first pressure; after reducing the pressure in the process chamber below the first pressure, increasing the pressure in the process chamber to a second pressure higher than the first pressure; and after increasing the pressure to the second pressure, depositing a tungsten-containing layer on each substrate of the plurality of substrates.

In some embodiments, each substrate of the plurality of substrates has a three-dimensional (3-D) structure including sidewalls, a plurality of openings in the sidewalls leading to a plurality of features having a plurality of interior regions fluidically accessible through the plurality of openings. In some embodiments, the method further includes after depositing the tungsten-containing layer, filling the plurality of features with metal. In some embodiments, the first pressure is less than about 100 mTorr. In some embodiments, the second pressure is at least about 3 Torr. In some embodiments, reducing pressure in the process chamber is performed for between about 10 seconds to about 30 seconds. In some embodiments, the tungsten-containing layer is deposited on an aluminum oxide film. In some embodiments, the tungsten-containing layer has a thickness of about 10 to about 20 Å. In some embodiments, depositing the tungsten-containing layer includes performing a first set of cycles, and the first set of cycles is performed at each station. In some embodiments, depositing the tungsten-containing layer includes performing the first set of cycles, each cycle including (a)-(c): (a) causing formation of a tungsten sublayer by: (i) causing dosing of diborane (B₂H₆) to the process chamber and purging diborane from the process chamber one or more times; (ii) after (i), causing dosing of fluorine-containing tungsten precursor to the process chamber and purging the fluorine-containing tungsten precursor from the process chamber one or more times; (b) after (a), causing dosing of diborane to the process chamber and purging diborane from the process chamber; and (c) after (b), causing dosing of a nitriding agent to the process chamber to convert the tungsten sublayer to a tungsten nitride layer and purging the nitriding agent from the process chamber. In some embodiments, the nitriding agent is ammonia. In some embodiments, each deposition cycle includes two or more iterations of (i) before a first iteration of (ii) in the deposition cycle. In some embodiments, each deposition cycle includes at least 3 iterations of (ii). In some embodiments, each deposition cycle includes at least 5 iterations of (ii). In some embodiments, each of (b) and (c) is performed only once per deposition cycle. In some embodiments, a number of iterations of (ii) in each deposition cycle is greater than a number of iterations of (i). In some embodiments, each dose in (i) has a duration of between 1 and 2 seconds. In some embodiments, each purge in (i) has a duration of less than 5 seconds. In some embodiments, each dose in (ii) has a duration of less than 1 second. In some embodiments, each purge in (ii) has a duration of between 1 and 2 seconds. In some embodiments, a duration of the dosing in (b) is 2 to 10 times longer than a duration of each dose in (i). In some embodiments, a total volume of diborane to fluorine-containing tungsten precursor in (a) is at least 2:1. In some embodiments, the fluorine-containing tungsten precursor is WF₆.

In another aspect of the embodiments herein, a system is provided, the system including: a process chamber including a plurality of stations; a controller configured to execute machine-readable instructions for: indexing each substrate of a plurality of substrates to a corresponding station of the plurality of stations; after indexing all of the plurality of substrates to the corresponding stations, reducing pressure in the process chamber below a first pressure; after reducing the pressure in the process chamber below the first pressure, increasing the pressure in the process chamber to at least a second pressure higher than the first pressure; performing a first set of cycles, each cycle including (a)-(c): (a) causing formation of a tungsten sublayer by: (i) causing dosing of diborane (B₂H₆) to the process chamber and purging diborane from the process chamber one or more times; (ii) after (i), causing dosing of fluorine-containing tungsten precursor to the process chamber and purging the fluorine-containing tungsten precursor from the process chamber one or more times; (b) after (a), causing dosing of diborane to the process chamber and purging diborane from the process chamber; and (c) after (b), causing dosing of a nitriding agent to the process chamber to convert the tungsten sublayer to a tungsten nitride layer and purging the nitriding agent from the process chamber.

These and other features of the disclosure are described further below.

### BRIEF DESCRIPTION OF DRAWINGS

FIGS. 1A-1E present different views and aspects of an example 3-D NAND structure.

FIGS. 2A and 2B present schematic representations of a features having conformal barrier layers.

FIGS. 3 and 4 are process flow diagrams illustrating certain operations in methods of depositing tungsten nitride layers.

FIG. 5 presents a graphical representation of various pulse sequences for depositing tungsten nitride.

FIG. 6 is a process flow diagram illustrating certain operations in methods of filling a feature with metal.

FIGS. 7A-B present graphical representations of indexing wafers according to various embodiments herein.

FIGS. 8-9 show schematic representations of apparatuses that may be used to perform the methods described herein.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Provided herein are methods of forming tungsten-containing layers in features, including tungsten nitride (WN) barrier layers in features. In particular embodiments, the methods are used to fill wordline features in 3D NAND structures. However, the methods may also be used for WN barrier layer formation in other features including tungsten vias and other vertically-oriented features.

The methods described herein are performed on a substrate that may be housed in a chamber. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon.

Substrates may have features such as via or contact holes, which may be characterized by one or more of narrow and/or re-entrant openings, constrictions within the feature, and high aspect ratios. A feature may be formed in one or more of the above-described layers. For example, the feature may be formed at least partially in a dielectric layer. In some embodiments, a feature may have an aspect ratio of at least about 2:1, at least about 4:1, at least about 6:1, at least about 10:1, at least about 25:1, or higher. One example of a feature is a hole or via in a semiconductor substrate or a layer on the substrate.

For some metallization schemes, an adhesion layer and/or barrier layer may be formed to line a feature prior to filling it with metal. A diffusion barrier is a layer that prevents diffusion of species between layers. An adhesion layer is a layer that promotes adhesion of a layer to an underlying layer.

For certain tungsten metallization applications, tungsten nitride (WN) diffusion barriers may be used. WN barriers have several advantages over barriers such as a titanium adhesion/titanium nitride barrier (Ti/TiN) bilayers. These include the ability to conformally deposit thin WN layers and the ability to deposit WN directly on dielectrics without an adhesion layer. These advantages allow more of the space available to be filled with W, lowering the overall contact resistance. Further, deposition of a WN layer can be performed at much lower temperatures than Ti/TiN, making it advantageous for low thermal budget applications.

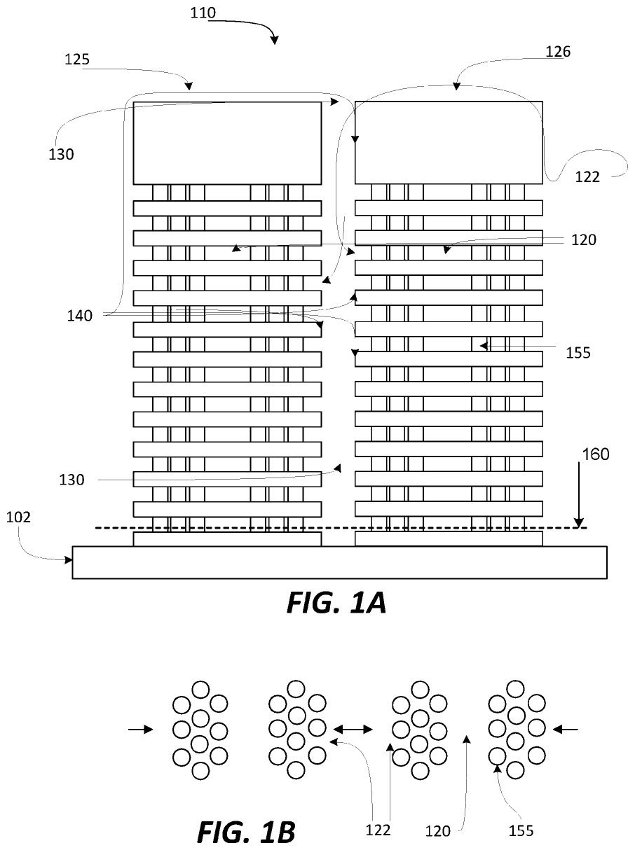

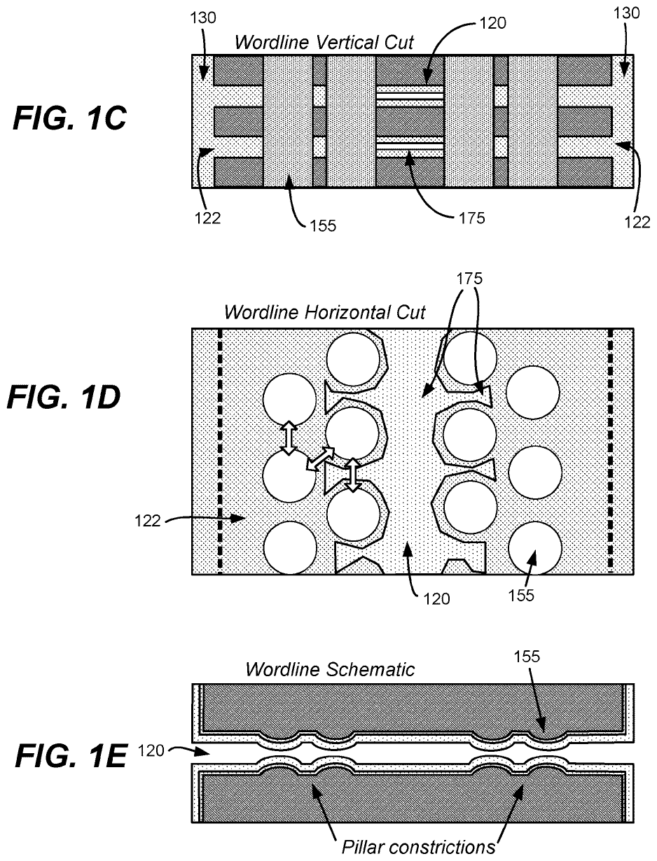

In some embodiments, the methods are used to deposit WN barrier layers prior to wordline fill in 3-D NAND structures. FIG. 1A presents a cross-sectional side-view of a 3-D NAND structure 110 (formed on a silicon substrate 102) having VNAND stacks (left 125 and right 126), central vertical structure 130, and a plurality of stacked horizontal features 120 with openings 122 on opposite sidewalls 140 of central vertical structure 130. Note that FIG. 1A displays two stacks of the exhibited 3-D NAND structure 110, which together form the trench-like central vertical structure 130. There may be more than two such stacks arranged in sequence and running spatially parallel to one another with the gap between each adjacent pair of stacks forming a central vertical structure 130, like that illustrated in FIG. 1A. The horizontal features 120 are 3-D memory wordline features that are fluidically accessible from the central vertical structure 130 through the openings 122. The horizontal features 120 present in both the 3-D NAND stacks 125 and 126 shown in FIG. 1A (i.e., the left 3-D NAND stack 125 and the right 3-D NAND stack 126) are also accessible from the other sides of the stacks (far left and far right, respectively) through similar vertical structures formed by additional 3-D NAND stacks (to the far left and far right, but not shown). In other words, each 3-D NAND stack 125, 126 contains a stack of wordline features that are fluidically accessible from both sides of the 3-D NAND stack through a central vertical structure 130. In the particular example schematically illustrated in FIG. 1A, each 3-D NAND stack contains 6 pairs of stacked wordlines; however, in other embodiments, a 3-D NAND memory layout may contain any number of vertically stacked pairs of wordlines.

The wordline features in a 3-D NAND stack may be formed by depositing an alternating stack of silicon oxide and silicon nitride layers, and then selectively removing the nitride layers leaving a stack of oxide layers having gaps between them. These gaps are the wordline features. Any number of wordlines may be vertically stacked in such a 3-D NAND structure so long as there is a technique for forming them available, as well as a technique available to successfully accomplish (substantially) void-free fills of the vertical features. Thus, for example, a 3-D NAND stack may include between 2 and 512 horizontal wordline features, or between 2 and 256 horizontal wordline features, or between 8 and 128 horizontal wordline features, or between 16 and 64 horizontal wordline features, and so forth (the listed ranges understood to include the recited end points).

FIG. 1B presents a cross-sectional top-down view of the same 3-D NAND structure 110 shown in side-view in FIG. 1A with the cross-section taken through the horizontal section 160 as indicated by the dashed horizontal line in FIG. 1A. The cross-section of FIG. 1B illustrates several rows of pillars 155, which run vertically from the base of semiconductor substrate 102 to the top of 3-D NAND structure 110. In some embodiments, these pillars 155 are formed from a polysilicon material. Polysilicon pillars may serve as gate electrodes for stacked memory cells formed within the pillars. The top-view of FIG. 1B illustrates that the pillars 155 form constrictions in the openings 122 to horizontal features 120—i.e. fluidic accessibility of horizontal features 120 from the central vertical structure 130 via openings 122 (as indicated by the arrows in FIG. 1B) is inhibited by pillars 155. This reduction in fluidic accessibility increases the difficulty of uniformly filling horizontal features 120 with material. The structure of horizontal features 120 and the challenge of uniformly filling them with material due to the presence of pillars 155 is further illustrated in FIGS. 1C, 1D, and 1E.

FIG. 1C exhibits a vertical cut through a 3-D NAND structure similar to that shown in FIG. 1A, but here focused on a single pair of horizontal features 120. FIG. 1C also schematically illustrates a void 175 in the filled horizontal features 120. FIG. 1D also schematically illustrates void 175, but in this figure illustrated via a horizontal cut through pillars 155, similar to the horizontal cut exhibited in FIG. 1B. FIG. 1E illustrates the accumulation of tungsten or other metal around the constriction-forming pillars 155, the accumulation resulting in the pinch-off of openings 122, so that no additional metal can be deposited in the region of voids 175. Apparent from FIGS. 1C and 1D is that void-free wordline fill relies on migration of sufficient quantities of deposition precursor down through vertical structure 130, through openings 122, past the constricting pillars 155, and into the furthest reaches of horizontal features 120, prior to the accumulated deposition of metal around pillars 155 causing a pinch-off of the openings 122 and preventing further precursor migration into horizontal features 120. Similarly, FIG. 1E exhibits a single wordline feature 120 viewed cross-sectionally from above and illustrates how a generally conformal deposition of material begins to pinch-off the interior of wordline feature 120 because the significant width of pillars 155 acts to partially block, and/or narrow, and/or constrict what would otherwise be an open path through wordline feature 120. (It should be noted that the example in FIG. 1E can be understood as a 2-D rendering of the 3-D features of the structure of the pillar constrictions shown in FIG. 1D, thus illustrating constrictions that would be seen in a plan view rather than in a cross-sectional view.)

The challenges due to reduced fluidic accessibility similarly affect deposition of WN barrier layers. While deposition may be thin enough that pinch-off does not occur, obtaining WN barrier layers of uniform thickness can be challenging. These challenges increase as 3D NAND structure become more complex. In some embodiments, for example, reactants may diffuse past at least 5, at least 10, at least 15, at least 20, at least 25, or at least 30 pillars to reach the innermost wordline feature. With an increasing number of pillars, the opportunity for non-uniform deposition occurs.

Another challenge in depositing WN layers is preventing fluorine incorporation in the film and underlying dielectric. Tungsten hexafluoride (WF₆) is a useful precursor as it is a gas at standard conditions, unlike many tungsten halide compounds. However, its use in typical tungsten deposition results in unacceptably high levels of fluorine. Described below are methods of depositing WN using WF₆ that result in WN films with very low levels of fluorine. As a result, the WN layers are very good diffusion barriers. Subsequent processing to fill the feature with tungsten can also employ WF₆ as the WN barrier layers prevent fluorine diffusion.

Examples of deposition in horizontally-oriented and vertically-oriented features are described herein. It should be noted that in at least most cases, the examples are applicable to both horizontally-oriented and vertically-oriented features. Moreover, it should also be noted that in the description below, the term “vertical” may be used to refer to a direction generally orthogonal to the plane of the substrate and the term “lateral” or “horizontal” to refer to a direction generally parallel to the plane of the substrate.

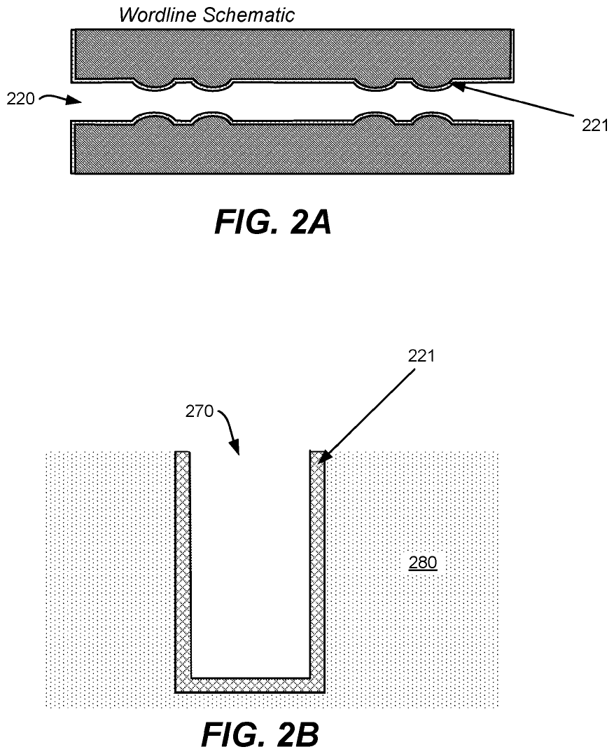

FIG. 2A depicts a schematic example of a wordline feature 220 in a 3D NAND structure. In FIG. 2A, a 2-D rendering of 3-D features of a partially-fabricated 3D NAND structure prior to tungsten fill, is shown including the wordline feature 220 and a conformal WN barrier layer 221. The pillar constrictions are shown in the figure representing constrictions that would be seen in a plan rather than cross-sectional view. The conformal WN barrier layer 221 may be deposited on a dielectric layer (not shown) such an aluminum oxide or other dielectric.

FIG. 2B depicts a schematic example a vertically-oriented feature 270 formed in a dielectric layer 280. Dielectric layer 280 may be silicon oxide, aluminum oxide, or any other appropriate dielectric material. A conformal WN barrier layer 221 lines the feature 270.

For conformal deposition of a WN layer, an atomic layer deposition (ALD) sequence may be used. Such a sequence can employ the following operations (performed in various orders): (i) providing a layer of reducing agent on a substrate surface, (ii) contacting the substrate surface with a tungsten-containing precursor to form a tungsten layer on the substrate, and (iii) nitriding the tungsten layer to form tungsten nitride. Each of these operations can involve delivering a dose of a reactant (reducing agent, tungsten-containing precursor, and/or nitriding agent) to a chamber housing a substrate including the feature. Purges are performed between these doses to purge out the reactants from the chamber.

For a diborane (B₂H₆) reducing agent, WF₆ precursor, and ammonia (NH₃) nitriding agent, a sequence can be expressed as B/W/N, with B representing a B₂H₆ dose+purge, W representing a WF₆ dose+purge, and N representing a NH₃ dose+purge. This sequence can be repeated for multiple cycles to deposit a WN layer. However, it can result in high fluorine content. While long dose/long purge sequences are often used, these can increase the fluorine content. In other embodiments, hydrogen (H₂) may be used as a reducing agent instead of diborane or in addition to diborane. Using H₂ instead of or in addition to diborane may reduce boron concentration in the resulting WN film.

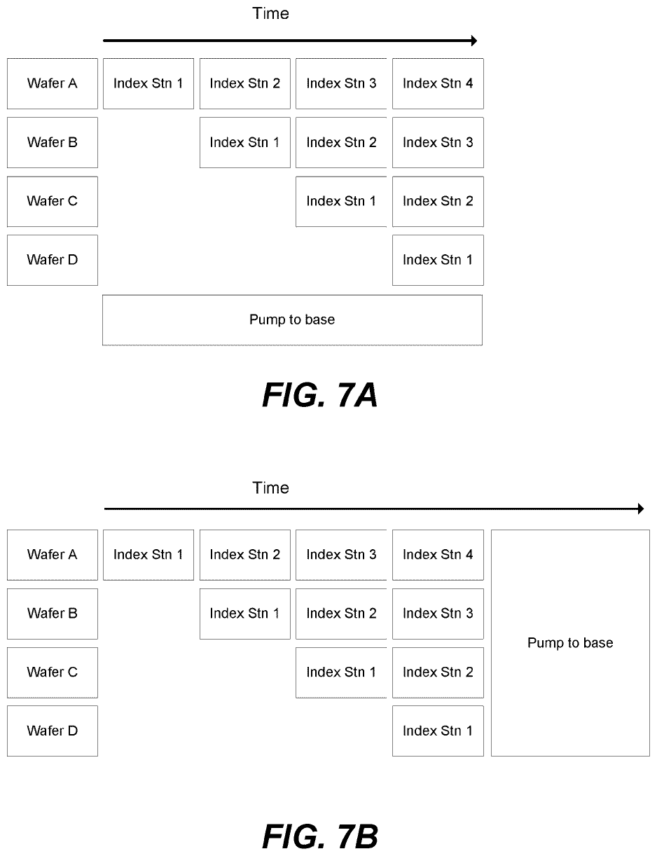

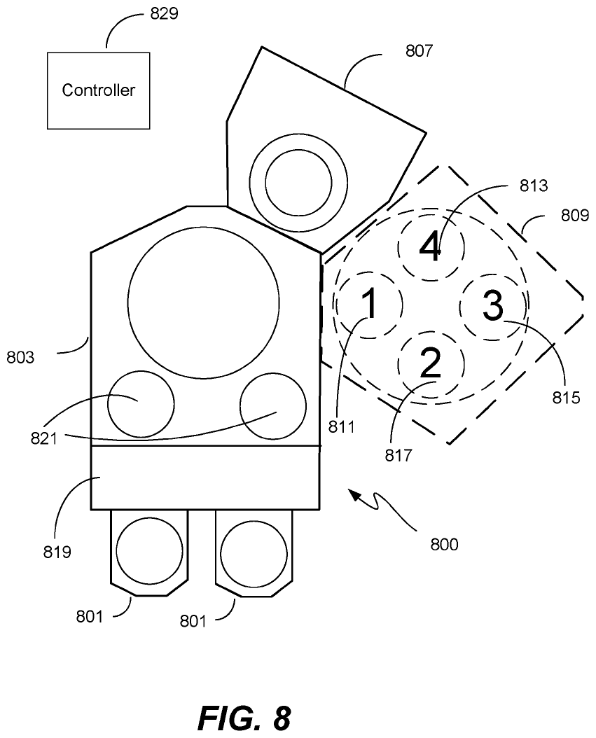

Another challenge in depositing WN layers is reducing surface moisture and evacuating undesirable species from the chamber, in particular nitriding agents such as NH₃, which may undesirably react with the wafer. In some embodiments a “pump to base” operation may be performed, during which the pressure in the process chamber may be reduced below a pressure to be used for processing wafers. After the pump to base operation is performed the pressure in the process chamber may be increased prior to deposition operations. Performing a pump to base operation may improve evacuation of undesirable species and improve uniformity of deposition in 3D NAND structures. Various embodiments of pump to base operations are discussed further below in respect to FIGS. 7A-B and 8.

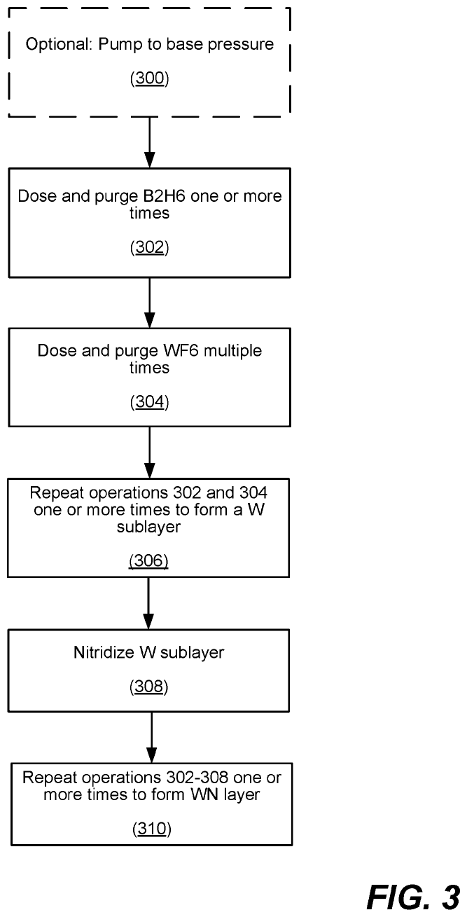

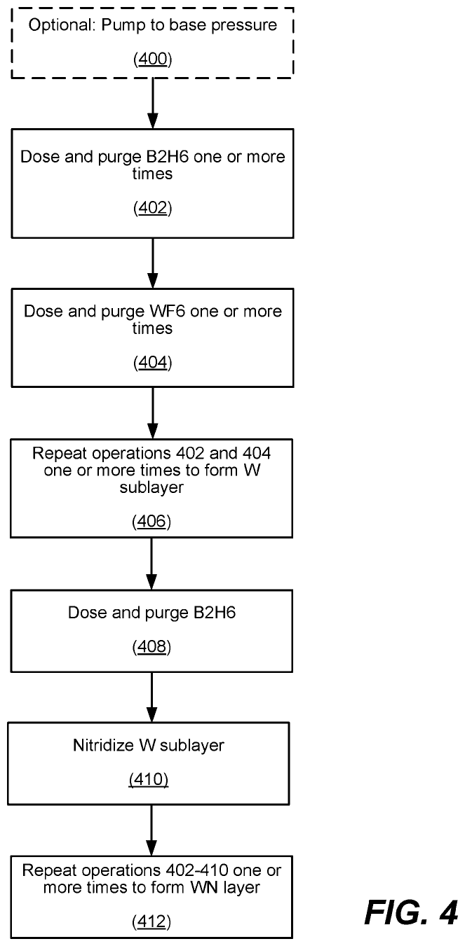

Provided herein are WN ALD sequences that use WF₆ but result in low fluorine content. FIGS. 3 and 4 show examples of WN ALD sequences according to certain embodiments. While FIGS. 3 and 4 discuss WN nitride deposition using WF₆ and B₂H₆, other deposition species and reducing agents may be used, including hydrogen-containing species and reducing agents that do not include boron.

First in FIG. 3, an optional process may be performed to reduce a pressure in the process chamber to a base pressure in an optional operation 300. Reducing pressure in the process chamber prior to deposition operations may evacuated reactants remaining from a prior process, in particular nitriding agents as discussed further below. During operation 300 the pressure may be reduced to a base pressure that is less than a pressure at which the other deposition processes may be performed. Then, B₂H₆ is dosed and purged one or more times in an operation 302. Then, in an operation 304, WF₆ is dosed and purged multiple times. Operations 302 and 304 are repeated one or more times to form a W sublayer in an operation 306. In some other embodiments, one iteration of operations 302 and 304 may be sufficient to form the W sublayer. The W sublayer is nitridized in an operation 308. Operation 308 can involve a NH₃ dose and purge. In other embodiments, other nitriding agents may be used, with examples including a hydrazine dose or exposure to a plasma generated from N₂. Operations 302 to 308 are then repeated one or more times to form the WN layer in an operation 310. In some embodiments, one iteration of operations 302 to 308 may be used to form the WN layer. In the example of FIG. 3, at least the B₂H₆ and WF₆ doses may be pressurized to increase reaction efficiency.

FIG. 4 shows another example of a process. The pressure in the process chamber may be optionally reduced to a base pressure in an optional operation 400. Then, B₂H₆ is dosed and purged one or more times in an operation 402. Then, in an operation 404, WF₆ is dosed and purged one or more times. Operations 402 and 404 are repeated one or more times to form a W sublayer in an operation 406. In some other embodiments, one iteration of operations 402 and 404 may be sufficient to form the W sublayer. Prior to nitridization, B₂H₆ is dosed and purged in an operation 408. This is done without a subsequent WF₆ dose and without forming more W prior to nitridization. The W sublayer is nitridized in an operation 410. Operation 410 can involve a NH₃ dose and purge. In other embodiments, other nitriding agents may be used, with examples including a hydrazine dose or exposure to a plasma generated from N₂. Operations 402 to 410 are then repeated one or more times to form the WN layer in an operation 412. At least the B₂H₆ and WF₆ doses may be pressurized to increase reaction efficiency.

Examples of these and other sequences are described further below.

According to the various embodiments, a sequence may be expressed as ((BP)ₓ/(WP)_{y})_{z}B/P/N/P, with “B” referring to a diborane pulse, “P” a purge, “W” a tungsten hexafluoride dose, and “N” an ammonia dose. To simplify, the sequence can be expressed without the purge operations as (BₓW_{y})_{z}BN. In these expressions, x is the number of consecutive B₂H₆ doses, y is the number of consecutive WF₆ doses, z is the number of times B₂H₆ and WF₆ are looped. Purges are used between all doses, though in some embodiments, they may be omitted between consecutive doses of the same reactant.

In some embodiments, x is an integer greater than or equal to 1, y is an integer greater than or equal to 5, and z is an integer greater than or equal to 1. In the same or other embodiments, x is an integer greater than or equal to 1, y is an integer greater than x, and z is an integer greater than or equal to 1.

According to various embodiments, the x B₂H₆ dose or doses in the (BₓW_{y}) loop may each have a duration of between 1 and 2 seconds. The x purge or purges following the B₂H₆ dose may have a duration of less than 5 seconds, or less than 3 seconds.

According to various embodiments, the x B₂H₆ dose or doses in the (BₓW_{y}) loop may each have a duration longer than the duration of each purge or purges following B₂H₆.

According to various embodiments, the y WF₆ dose or doses in the (BₓW_{y}) loop may each have a duration of less than 1 second. The y purge or purges following the WF₆ dose may have a duration of between 1 and 2 seconds.

According to various embodiments, the y WF₆ dose or doses in the (BₓW_{y}) loop may each have a duration less than the duration of the purge or purges following WF₆.

The diborane dose after the (BₓW_{y}) loop and prior to the NH₃ dose may be significantly longer than each x diborane dose. For example, it may be 2-10 times longer than each diborane dose in the (BₓW_{y}) loop. In some embodiments, it may be 10 seconds or less.

According to various embodiments, a charge volume (also referred to as a line changer) may be used to pressurize the reactants prior to each dose. The use of multiple short, pressurized doses facilitates an efficient reaction between B₂H₆ and WF₆, resulting in less fluorine incorporation. It also improves throughput.

The use of a B₂H₆ pulse prior to the NH₃ pulse allows B₂H₆ to react with incorporated fluorine, producing boron trifluoride (BF₃), which can be purged prior to nitridation. In some embodiments, an H₂ dose may be used instead or in addition to B₂H₆ to form hydrogen fluoride (HF). For example, a pulse sequence may be expressed as (BₓW_{y})_{z}HN or (BₓW_{y})_{z}(B+H)N, wherein H is a dose of H₂.

A sequence described above, (BₓW_{y})_{z}BN, (BₓW_{y})_{z}HN, or (BₓW_{y})_{z}(B+H)N, can be repeated one or more time to deposit the desired thickness of WN. According to various embodiments, 2 to 4 total sequences are used to form 10 to 20 Å. Further, as described above, the diborane or hydrogen dose immediately prior to the ammonia dose may be omitted.

According to various embodiments, the total volume of B₂H₆ to WF₆ in the (BₓW_{y}) loop may be about 2:1 or higher.

The ratio of reducing agent to precursor may be characterized as the ratio of molecules that the substrate is exposed to and are available to react. It may be calculated from:

$$\frac{Reducing agent flow rate \times ( Reducing agent line charge time + Reducing agent dose time )}{Precursor flow rate \times ( Precursor line charge time + Precursor dose time )}$$

Line charges are pressurized distributions. Dose time refers to the amount of time the dose lasts. This may be simplified to the below where there is no line charge time:

$$\frac{Reducing agent flow rate \times Reducing agent dose time}{Precursor flow rate \times Precursor dose time}$$

This ratio may be between 1.5:1 to 4:1 in some embodiments. In some embodiments, it may be about 2:1.

The reduction in fluorine was demonstrated as follows. WN was deposited on an Al₂O₃ aluminum oxide surface using different ALD sequences of B₂H₆ and WF₆ as shown in the table below. Fluorine concentration in the deposited WN film and at the WN:Al₂O₃ was measured.

| | F level (atoms/cc) - | F level (atoms/cc) - |
|---|---|---|
| Sequence | in-film | interface |
| BWN (long dose, | 3.0E21 | 1.0E21 |
| long purge) | | |
| B₃W₅)₂N | 1.0E20 | 1.0E19 |
| (B₃W₅)₂BN | 3.5E18 | 1.4E18 |

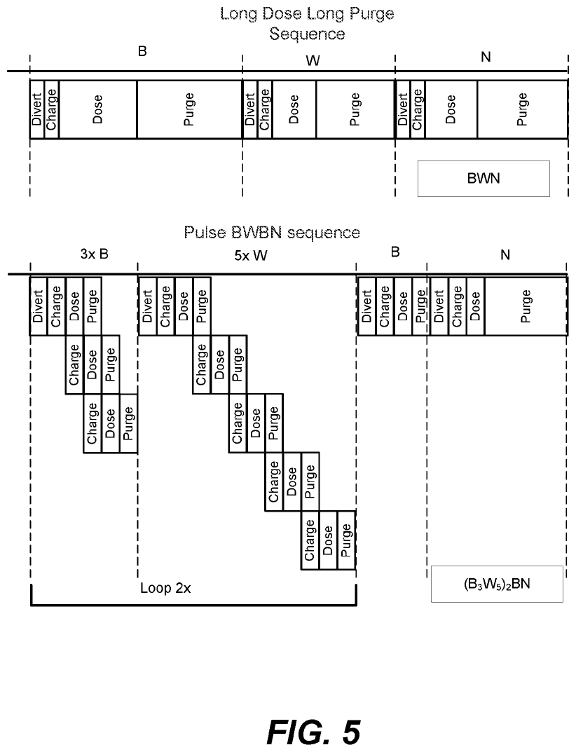

FIG. 5 provides a graphical illustration of the BWN and (B₃W₅)₂BN sequences used. The dose times in the BWN sequence are significantly longer than those in the (B₃W₅)₂BN sequences as can be seen in FIG. 5. The results show that the process in FIG. 3 and FIG. 4 result in significantly reduced fluorine.

According to various embodiments, each of operations 302, 304, and 308 in FIG. 3 and each of operations 402, 404, 408 and 410 in FIG. 4 may be performed in the same processing chamber or in different processing chambers. If performed in the same chamber, they may be performed in a single-station or multi-station chamber. In a multi-station chamber, various operations may be performed at various stations. For example, operation 302 may be performed in a first station, operation 304 in a second station, and operation 308 in a third station.

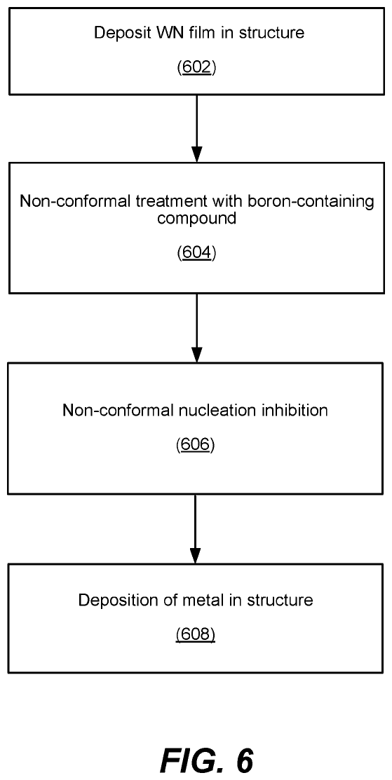

After deposition of a WN layer, in some embodiments, the features may be filled with W or other metal. FIG. 6 is a process diagram illustrating operations in filling a structure with metal according to various embodiments. First, a WN film is deposited in the structure in an operation 602. This may be performed as described above and is a generally conformal deposition that lines the exposed surfaces of the structures. For example, in a 3D NAND structure such as that shown in FIG. 1A, the film lines the horizontal features 120. In some embodiments, W is deposited conformally in the structure in an operation that may be referred to as Dep1. This can involve ALD deposition of W. In some embodiments, includes ALD deposition of a nucleation layer followed by ALD bulk deposition. Further description of ALD processes are given below.

Next, in an operation 604, the structure is non-conformally treated with a boron-containing compound. Non-conformal treatment in this context refers to the treatment being preferentially applied at least at narrow passage or feature opening than in the further in the feature interior. In many embodiments, the boron-containing compound is diborane (B₂H₆). Treating the features with a boron-containing chemistry increases the inhibition effect of the subsequently applied inhibition treatment. This effect may be due to elemental boron forming onto the surface, diborane (or other compound) adsorbing onto the surface, or some combination of these.

According to various embodiments, the treatment in operation 604 may be performed directly on the WN film formed in operation 602 or may be performed on a Dep1 W film if formed.

Examples of other boron-containing compounds include boranes including BₙHₙ₊₄, BₙHₙ₊₆, BₙHₙ₊₈, BₙHₘ, where n is an integer from 1 to 10, and m is a different integer than n. Other boron-containing compounds may be used, e.g., alkyl boranes, alkyl boron, aminoboranes (CH₃)₂NB(CH₂)₂, carboranes such as C₂BₙHₙ₊₂, and borane halides such as B₂F₄.

The structure is non-conformally exposed to the boron-containing gas. Diborane is self-decomposing gas. If the amount of diborane is limited (e.g., by one or more of diborane concentration, flow rate, and dose time), the gas will decompose closer to the feature opening without diffusing further into the feature. For 3D NAND structures, the treatment may be conformal in the vertical direction such that the bottom wordline feature is treated to approximately the same extent as the top wordline feature, while non-conformal in that the interior of the wordline features are not exposed to the treatment or to a significantly lesser extent than the narrow passage or feature opening.

In a 3D-NAND structure for example, the diborane will decompose at an outer wordline without diffusing into the innermost wordline. Since the diffusion of diborane is easier to control than the diffusion of an inhibition gas such as NF₃ and diborane increases the inhibition effect of NF₃, it can be used to control the inhibition profile.

Operation 604 can involve a continuous dose or multiple doses of a boron-containing chemistry, separated by purges. Using multiple short doses can facilitate in preventing diffusion further into the feature than desired.

According to various embodiments, diborane may be provided with a nitrogen carrier gas (e.g., 5%/95% B₂H₆/N₂). Argon may be used to further dilute the diborane, e.g., 1:1 Ar:(B₂H₆/N₂) or 2:1 (B₂H₆/N₂).

Substrate temperature during operation 604 may be limited to control the extent of the inhibition. In some embodiments, it is no more than 300° C. or no more than 250° C.

In some embodiments, diborane may be co-flowed with hydrogen (H₂). Hydrogen may be used as parameter to control diborane exposure profile. Diborane decomposes more slowly in the presence of hydrogen than in another carrier gas such as nitrogen (N₂). Thus, for faster decomposition at the outer wordline (or other feature opening), hydrogen may be omitted. For complex structures in which the diborane treatment reaches further into the structure, hydrogen may be added. For example, in some 3D NAND structures with multiple pillars, hydrogen may be added to allow the diborane to pass one or more pillars before decomposing or otherwise treating the film.

After the non-conformal treatment with a boron-containing compound, nucleation in the structure is non-conformally inhibited in an operation 606. As with operation 604, non-conformal treatment in this context refers to the treatment being preferentially applied at least at narrow passage or feature opening than in the further in the feature interior. For 3-D NAND structures, the treatment may be conformal in the vertical direction such that the bottom wordline feature is treated to approximately the same extent as the top wordline feature, while non-conformal in that the interior of the wordline features are not exposed to the treatment or to a significantly lesser extent than the narrow passage or feature opening.

Nucleation inhibition inhibits subsequent metal nucleation at the treated surfaces. It can involve one or more of: deposition of an inhibition film, reaction of treatment species with the metal film to form a compound film, and adsorption of inhibition species. During the subsequent deposition operation, there is a nucleation delay on the inhibited portions of the underlying film relative to the non- or lesser-inhibited portions.

In some embodiments, NF₃ is used in a thermal inhibition process. Other nitrogen-containing gases such as ammonia (NH₃) or hydrazine (N₂H₄) may be used for thermal inhibition processes. The inhibition may also be a plasma inhibition, with a nitrogen-containing gas such as N₂ used to generate a plasma in a remote or in-situ chamber.

To tailor lateral non-conformality in the wordlines, pressure and treatment gas flow rate may be adjusted. Higher chamber pressure and lower treatment gas flow rate (and/or concentration) promotes treatment at the openings of the wordline features over treatment within the interiors of the wordline features. Thus, in some embodiments, chamber pressure may lower from operation 602 to 606. Example chamber pressures range from 3 Torr to 40 Torr. And, because the diborane increases the inhibition effect, non-conformality of the inhibition can be controlled by the operation 604 as well as the parameters of operation 606.

In some embodiments, a treatment gas is pressurized to level significantly higher than the chamber pressure prior to introduction to chamber. This facilitates the gas reaching the bottommost portion of the vertical structure. In the example of NF₃ gas, the NF₃ gas may be pressurized in a charge volume to a pressure between 10 Torr and 1000 Torr. In some embodiments, the pressure is between 400 Torr and 500 Torr.

Operation 606 may be a continuous flow or pulsed process. In the latter case, different gases may be pulsed in sequence to tune the treatment.

After operation 606, a W deposition is performed in operation 608. Operation 608 may involve an ALD or CVD process. For deposition into 3D NAND structures, an ALD process may be used to allow for good step coverage throughout the structure. Gases more easily reach feature interiors due to the effects of the treatment. After an etch process, film deposited near the feature entrance is removed, allowing more space for gases to reach the interior of the feature and preventing pinch-off. In some embodiments, enough metal film may be removed such that an underlying surface is wholly or partially exposed, increasing nucleation delay at these areas. After an inhibition process, nucleation delay is increased, allowing an inside-out fill process. Operation 608 may complete fill of the structures in some embodiments. In other embodiments, one or more additional treatment/deposition operations may be performed.

According to various embodiments, each of operations 602, 604, 606, and 608 may be performed in the same processing chamber or in different processing chambers. If performed in the same chamber, they may be performed in a single-station or multi-station chamber. In a multi-station chamber, various operations may be performed at various stations. For example, operation 602 may be performed in a first station, operation 604 in a second station, operation 606 in a third station, and operation 608 in a fourth station. Still further, operation 602 may be performed in multiple stations.

In some embodiments, while various operations are performed in separate stations within a single chamber, only a single operation, i.e., operation 602, depositing WN in a structure, may be performed at a time. In another embodiment, when multiple substrates are being processed, various operations may occur concurrently. For example, a first substrate is at station one for operation 602 and a second substrate is at station two for operation 606 in the same multi-station chamber. Both operation 604 and operation 606 may proceed concurrently in the same multi-station chamber. In some embodiments, chamber pressure may be low to prevent any cross-contamination or safety issues. In one example, in operation 604, a structure may be treated using a boron-containing compound (e.g., B₂H₆) in station one on a first substrate. A second substrate may be undergoing operation 604 using NF₃ in a station two. Both the B₂H₆ treatment in station one and the NF₃ in station two can occur concurrently in the same multi-station chamber. To achieve this, the chamber pressure is set to a lower pressure, such as a pressure below 25 Torr.

In the examples above, deposition of a conformal layer can involve deposition of a nucleation layer. While the nucleation layer can serve as the initial conformal layer in some embodiments, a conformal bulk layer may be deposited on the nucleation layer to form the conformal layer of the initial metal deposition.

A nucleation layer is a layer that facilitates subsequent deposition of bulk metal-containing material thereon. It is typically thin and conformal. According to various implementations, a metal nucleation layer may be deposited prior to any fill of the feature and/or at subsequent points during fill of the feature.

In certain implementations, the nucleation layer is deposited using a cyclical process of sequentially adding reactants for reaction in the feature. The may be an atomic layer deposition (ALD) process and/or a pulsed nucleation layer (PNL) technique. In such a technique, pulses of a reducing agent, optional purge gases, and metal-containing precursor are sequentially injected into and purged from the reaction chamber. The process is repeated in a cyclical fashion until the desired thickness is achieved. PNL techniques for depositing tungsten nucleation layers are described in U.S. Pat. Nos. 6,635,965; 7,005,372; 7,141,494; 7,589,017, 7,772,114, 7,955,972 and 8,058,170, and U.S. Patent Publication No. 2010-0267235, all of which are incorporated by reference herein in their entireties.

Nucleation layer thickness can depend on the nucleation layer deposition method as well as the desired quality of bulk deposition. In general, nucleation layer thickness is sufficient to support high quality, uniform bulk deposition. Examples may range from 5 Å-100 Å, e.g., 5 Å to 30 Å.

In certain implementations, a bulk layer may be deposited directly in a feature without use of a nucleation layer. For example, in some implementations, the feature surface and/or an already-deposited under-layer supports bulk deposition.

Tungsten nucleation layer deposition can involve exposure to alternating pulses of a tungsten-containing precursor (also referred to as a tungsten precursor) and a reducing agent, separated by an inert purge gas. For tungsten deposition, examples of precursors include tungsten hexafluoride (WF₆). Chlorine-containing tungsten precursors (WClₓ) such as tungsten pentachloride (WCl₅) and tungsten hexachloride (WCl₆) may be used. These precursors may be reduced to elemental tungsten (W) by reaction with reducing agents such as silane (SiH₄) and diborane (B₂H₆).

In alternate embodiments, a metal precursor and a reducing agent may be co-flowed. If co-flowed, a sequence in which the metal precursor and reducing agent are co-flowed in pulses may be used. During the reactant doses, the metal precursor and reducing agent are co-flowed into the chamber. Co-flowing the reactants is more similar to a CVD reaction, which results in a higher deposition rate and rougher nucleation layer. Various modifications may be made to the sequence. For example, the metal precursor and reducing agent reactant pulses may be offset but overlap with a delay for one reactant with respect to the other. In another example, the inert gas may be pulsed for the purge phase.

Examples of reducing agents can include boron-containing reducing agents including B₂H₆ and other boranes, silicon-containing reducing agents including SiH₄ and other silanes, hydrazine, and germanes. In some implementations, pulses of tungsten-containing precursors can be alternated with pulses of one or more reducing agents, e.g., S/W/S/W/B/W, etc., where W represents a tungsten-containing precursor, S represents a silicon-containing precursor, and B represents a boron-containing precursor. In some implementations, a separate reducing agent may not be used, e.g., an organometallic tungsten-containing precursor may undergo thermal or plasma-assisted decomposition.

According to various implementations, hydrogen may or may not be run in the background. Further, in some implementations, deposition of a tungsten nucleation layer may be followed by one or more treatment operations prior to tungsten bulk deposition. Treating a deposited tungsten nucleation layer to lower resistivity is described for example in U.S. Pat. Nos. 7,772,114 and 8,058,170 and U.S. Patent Publication No. 2010-0267235, incorporated by reference herein.

Bulk deposition can occur by an ALD or CVD process. In a CVD process, a reducing agent and a metal precursor are co-flowed into a deposition chamber to deposit a bulk fill layer in the feature. An inert carrier gas may be used to deliver one or more of the reactant streams, which may or may not be pre-mixed. This operation generally involves flowing the reactants continuously until the desired amount is deposited. In certain implementations, the CVD operation may take place in multiple stages, with multiple periods of continuous and simultaneous flow of reactants separated by periods of one or more reactant flows diverted.

For conformal deposition and deposition into complex structures such as 3D NAND structures, ALD deposition of a bulk layer may be used. ALD deposition of a bulk layer involves exposure to alternating pulses of a metal-containing precursor and a reducing agent, separated by an inert purge gas, using the metal precursors described above with reference to nucleation layer deposition. The same or different metal precursor used in nucleation layer deposition may be used for bulk deposition. In contrast to nucleation layer deposition in which a strong reducing agent such as diborane or silane may be used, hydrogen is often the reducing agent for bulk deposition.

Deposition may proceed according to various implementations until a certain feature profile is achieved and/or a certain amount of metal is deposited. In some implementations, the deposition time and other relevant parameters may be determined by modeling and/or trial and error. In some implementations, a process chamber may be equipped with various sensors to perform in-situ metrology measurements for end-point detection of a deposition operation. Examples of in-situ metrology include optical microscopy and X-Ray Fluorescence (XRF) for determining thickness of deposited films.

In some embodiments, the conformal tungsten layer may be characterized as low resistivity and, in some embodiments, low stress and/or low fluorine. Because the wordline features are unfilled (with the exception of the nucleation layer if deposited), a relatively fast deposition technique may be used. In some embodiments, this involves alternating pulses of a W-containing precursor, such as tungsten hexafluoride (WF₆), and hydrogen (H₂) or other reducing agent to deposit the first tungsten layer in an ALD process. Purge operations may separate the pulses. Relatively short pulse times may be used for deposition to increase throughput.

### Metal-Containing Precursors

As described above, WF₆ is used to deposit a WN layer. WF₆ is a useful precursor as it is in the gas phase at deposition conditions. For deposition of W nucleation and bulk layer, WF₆ may also be used. In some embodiments, other tungsten-containing precursors may be suitable for performing disclosed embodiments. For example, a metal-organic tungsten-containing precursor may be used. Organo-metallic precursors and precursors that are free of fluorine, such as MDNOW (methylcyclopentadienyl-dicarbonylnitrosyl-tungsten) and EDNOW (ethylcyclopentadienyl-dicarbonylnitrosyl-tungsten) may also be used. Chlorine-containing tungsten precursors (WClₓ) such as tungsten pentachloride (WCl₅) and tungsten hexachloride (WCl₆) may be used.

Deposition of other metals may be performed on the WN layers. These include molybdenum, ruthenium, and cobalt. To deposit molybdenum (Mo), Mo-containing precursors including molybdenum hexafluoride (MoF₆), molybdenum pentachloride (MoCl₅), molybdenum dichloride dioxide (MoO₂Cl₂), molybdenum tetrachloride oxide (MoOCl₄), and molybdenum hexacarbonyl (Mo(CO)₆) may be used.

To deposit ruthenium (Ru), Ru-precursors may be used. Examples of ruthenium precursors that may be used for oxidative reactions include (ethylbenzyl) (1-ethyl-1,4-cyclohexadienyl)Ru(0), (1-isopropyl-4-methylbenzyl) (1,3-cyclohexadienyl)Ru(0), 2,3-dimethyl-1,3-butadienyl)Ru(0)tricarbonyl, (1,3-cyclohexadienyl)Ru(0)tricarbonyl, and (cyclopentadienyl) (ethyl)Ru(II) dicarbonyl. Examples of ruthenium precursors that react with non-oxidizing reactants are bis(5-methyl-2,4-hexanediketonato)Ru(II) dicarbonyl and bis(ethylcyclopentadienyl)Ru(II).

To deposit cobalt (Co), cobalt-containing precursors including dicarbonyl cyclopentadienyl cobalt (I), cobalt carbonyl, various cobalt amidinate precursors, cobalt diazadienyl complexes, cobalt amidinate/guanidinate precursors, and combinations thereof may be used.

The metal-containing precursor may be reacted with a reducing agent as described above. In some embodiments, H₂ is used as a reducing agent for bulk layer deposition to deposit high purity films.

### Nucleation Layer Deposition

In some implementations, the methods described herein involve deposition of a nucleation layer prior to deposition of a bulk layer. In various implementations, nucleation layer deposition can involve exposure to a metal precursor as described above and a reducing agent. Examples of reducing agents can include boron-containing reducing agents including diborane (B₂H₆) and other boranes, silicon-containing reducing agents including silane (SiH₄) and other silanes, hydrazines, and germanes. In some implementations, pulses of metal-containing can be alternated with pulses of one or more reducing agents, e.g., S/W/S/W/B/W, etc., W representing a tungsten-containing precursor, S represents a silicon-containing precursor, and B represents a boron-containing precursor. In some implementations, a separate reducing agent may not be used, e.g., a tungsten-containing precursor may undergo thermal or plasma-assisted decomposition.

### Bulk Deposition

As described above, bulk deposition may be performed across a wafer. In some implementations, bulk deposition can occur by a CVD process in which a reducing agent and a metal-containing precursor are flowed into a deposition chamber to deposit a bulk fill layer in the feature. An inert carrier gas may be used to deliver one or more of the reactant streams, which may or may not be pre-mixed. Unlike PNL or ALD processes, this operation generally involves flowing the reactants continuously until the desired amount is deposited. In certain implementations, the CVD operation may take place in multiple stages, with multiple periods of continuous and simultaneous flow of reactants separated by periods of one or more reactant flows diverted. Bulk deposition may also be performed using ALD processes in which a metal-containing precursor is alternated with a reducing agent such as H₂. In some implementations, ALD may be used to deposit an initial bulk layer in a Dep1 process with CVD used for the remaining feature fill after inhibition. In some implementations, ALD may be used for feature fill with CVD used for an overburden layer. In some implementations, ALD may be used for all of the bulk layer deposition.

It should be understood that the metal films described herein may include some amount of other compounds, dopants and/or impurities such as nitrogen, carbon, oxygen, boron, phosphorous, sulfur, silicon, germanium and the like, depending on the particular precursors and processes used. The metal content in the film may range from 20% to 100% (atomic) metal. In many implementations, the films are metal-rich, having at least 50% (atomic) metal, or even at least about 60%, 75%, 90%, or 99% (atomic) metal. In some implementations, the films may be a mixture of metallic or elemental metal (e.g., W, Mo, Co, or Ru) and other metal-containing compounds such as tungsten carbide (WC), tungsten nitride (WN), molybdenum nitride (MoN) etc. CVD and ALD deposition of these materials can include using any appropriate precursors as described above.

### Inhibition of Metal Nucleation

Plasma inhibition processes involve exposure to a plasma generated from a nitrogen containing compound, such as N₂. Plasma power, chamber pressure, and/or process gases may be pulsed in some embodiments.

Thermal inhibition processes generally involve exposing the feature to a nitrogen-containing compound such as ammonia (NH₃) or hydrazine (N₂H₄) to non-conformally inhibit the feature near the feature opening. In some embodiments, the thermal inhibition processes are performed at temperatures ranging from 250° C. to 450° C. At these temperatures, exposure of a previously formed tungsten or other layer to NH₃ results in an inhibition effect. Other potentially inhibiting chemistries such as nitrogen (N₂) or hydrogen (H₂) may be used for thermal inhibition at higher temperatures (e.g., 900° C.). For many applications, however, these high temperatures exceed the thermal budget. In addition to ammonia, other hydrogen-containing nitriding agents such as hydrazine may be used at lower temperatures appropriate for back end of line (BEOL) applications. During thermal inhibition, a metal precursor may be flowed with the inhibition gas or in alternating pulses with the gas.

Nitridation of a surface can passivate it. Subsequent deposition of tungsten or other metal such as molybdenum or cobalt on a nitrided surface is significantly delayed, compared to on a regular bulk tungsten film. In addition to NF₃, fluorocarbons such as CF₄ or C₂F₈ may be used. However, in certain implementations, the inhibition species are fluorine-free to prevent etching during inhibition.

In addition to the surfaces described above, nucleation may be inhibited on liner/barrier layers surfaces such as TiN and/or WN surfaces. Any chemistry that passivates these surfaces may be used. Inhibition chemistry can also be used to tune an inhibition profile, with different ratios of active inhibiting species used. For example, for inhibition of W surfaces, nitrogen may have a stronger inhibiting effect than hydrogen; adjusting the ratio of N₂ and H₂ gas in a forming gas can be used to tune a profile.

In certain implementations, the substrate can be heated up or cooled down before inhibition. A predetermined temperature for the substrate can be selected to induce a chemical reaction between the feature surface and inhibition species and/or promote adsorption of the inhibition species, as well as to control the rate of the reaction or adsorption. For example, a temperature may be selected to have high reaction rate such that more inhibition occurs near the gas source.

After inhibition, the inhibition effect may be modulated as described above. In the same or other embodiments, it may also be modulated by soaking it in a reducing agent or metal precursor, exposing it to a hydrogen-(H-)containing plasma, performing a thermal anneal, exposing it an air, which can reduce the inhibition effect.

### Wafer Loading and Pump to Base

In various embodiments herein, processes for depositing tungsten nitride (WN) barrier layers and other layers are described. These deposition processes may be performed in a process chamber or tool having two, three, four, five, or even more deposition stations positioned within a single process chamber or tool. In some embodiments each station simultaneously performs an operation, while in other embodiments each station may perform different operations.

As noted above, in various embodiments a pump to base pressure operation is performed. This operation may be referred to as a “pump to base” operation, as described in operations 300 and 400, above. During a pump to base operation the pressure in the process chamber may be reduced below a pressure to be used for processing wafers. After the pump to base operation is performed the pressure in the process chamber may be increased to a greater pressure prior to deposition operations.

In some embodiments, the reduction in pressure may help reduce surface moisture or evacuate undesirable species from the chamber, in particular nitriding agents such as NH₃, which may undesirably react with the wafer. For example, as shown in FIG. 4, a nitridization operation may be performed after multiple cycles of dosing B₂H₆ and WF₆. As the processed wafers are removed from the chamber and new wafers are loaded into the chamber, nitrogen-containing reactants, such as NH₃, may remain and then react with the wafers prior to a new nitridization operation as the process of FIG. 4 is repeated. This unintended interaction of nitrogen-containing reactants with wafers is undesirable, and thus a pump to base operation may be performed to evacuate such species. Furthermore, reducing the pressure of the chamber to a base pressure lesser than an operating pressure at which deposition processes may be performed may increase the rate of evacuation, increasing throughput and improving film uniformity.

In some embodiments, the pump to base operation may improve the deposition rate of films. Generally, film growth rate is increased when a pump to base operation is performed. Thus, a pump to base operation may be used prior to deposition operations to improve the efficiency of the deposition process and increase throughput.

In some embodiments, a pump to base operation is performed while wafers are loaded into stations of a tool. A tool may have multiple stations, and wafers may be loaded into stations by placing each wafer on a first station, and then indexing the wafer to a different station while placing another wafer on the first station. This process may be completed until a wafer is present at each station. Operations described herein may then be performed to deposit layers on the wafers in each station. Notably, while each station may have its own pedestal and showerhead, a vacuum pump may be connected to the entire process chamber such that each station is at the same pressure as the other stations.

In some embodiments, wafer loading and indexing operations are performed simultaneously with a pump to base operation to improve efficiency and reduce the total time to index wafers and perform a pump to base operation. FIG. 7A presents an illustration of loading wafers A-D into stations 1-4. Each wafer may be loaded into station 1 initially, and then the previously loaded wafer or wafers may be indexed before a subsequent wafer is loaded into station 1 or simultaneously with the subsequent wafer being loaded into station 1. For example, wafer A is loaded into station 1, then indexed to station 2. During or after wafer A is indexed to station 2 wafer B is loaded into station 1 followed by indexing wafers A and B to stations 2 and 3, respectively, for the subsequent loading of wafer C. During these indexing operations a pump to base operation may be performed to reduce pressure in the tool and thus reduce pressure at each station. After each wafer is loaded the pump to base operation may be completed and subsequent deposition processes performed.

While this method of loading wafers and performing a pump to base operation increases throughput, it may also increase non-uniformity of deposition between stations. Deposition processes performed after performing an indexing and pump to base operation as shown in FIG. 7A result in different film thicknesses. For example, Wafer A has a different film growth rate than Wafer D. The difference in film growth rates is correlated to the order in which wafers are loaded into the tool and resulting exposure time of each wafer to a pump to base operation. This wafer to wafer (W2W) non-uniformity is undesirable.

This W2W non-uniformity may be particularly noticeable in embodiments where the same process is performed at each station. As noted elsewhere herein, in various embodiments processes described herein may be performed in the same station/process chamber or different stations/process chambers. In embodiments where each station performs a different operation, two stations may be used for dosing B₂H₆ and WF₆, respectively. In embodiments where different stations are performing different operations, W2W non-uniformity resulting from different exposure time to a pump to base operation may be diminished. For example, a wafer may enter a tool onto station 1, undergo a first process, indexed to station 2, undergo a second process, indexed to station 3, undergo a third process, indexed to station 4, undergo a fourth process, and be removed from the chamber for further processing elsewhere. During these indexing operations a process chamber may be pumped to base pressure, however there is a reduced disparity in exposure to base pressure between wafers as each wafer is processed at each station prior to indexing to a subsequent station.

Alternatively, in some embodiments, each station performs the same series of operations. In such embodiments, wafers may be loaded/indexed onto each station and operations described herein may be performed simultaneously at each station, e.g., the same or similar processes are performed at each station. Afterwards, each wafer may be indexed out of the tool for further processing elsewhere. In such an embodiment each wafer may have different exposure conditions, e.g., duration, to a base pressure when the pump to base pressure operation is performed during wafer indexing.

To reduce this W2W non-uniformity, a pump to base operation may be performed after wafers are placed onto each station. FIG. 7B presents an illustration of loading wafers into stations of a process chamber and, once a wafer has been placed onto each station, performing a pump to base operation. In some embodiments, this reduces W2W non-uniformity significantly. The table below presents film thicknesses based on loading wafers, performing a pump to base operation as described in FIGS. 7A and 7B, and performing deposition processes described herein. As shown in the table below, performing a pump to base operation after indexing a wafer onto each station improves W2W non-uniformity to less than 1 Angstrom.

| | Pump to Base During | Pump to Base After |
|---|---|---|
| Station | Indexing Thickness (A) | Indexing Thickness (A) |
| Station 1 | 17.2 | 12.8 |
| Station 2 | 14.7 | 12.6 |
| Station 3 | 13.3 | 11.9 |
| Station 4 | 12.2 | 12.0 |

Performing a pump to base operation after indexing reduces throughput compared to performing a pump to base operation during indexing but significantly improves W2W uniformity. In some embodiments, a pump to base operation performed after indexing may be at least about 15 seconds, at least about 20 seconds, at least about 30 seconds, at least about 40 seconds, between about 10 seconds and about 30 seconds, between about 20 seconds and about 40 seconds, about 30 seconds, about 40 seconds, or between about 20 seconds and about 60 seconds. In some embodiments the W2W non-uniformity may improve with increasing durations of a pump to base operation up to a saturation point within the durations noted above. While performing the pump to base operation after indexing reduces throughput, it significantly increases film deposition uniformity as shown in the table above.

In some embodiments, a pump to base operation may reduce chamber pressure to less than about 1 Torr, less than about 500 mTorr, less than about 300 mTorr, less than about 200 mTorr, between about 100 mTorr and about 1 Torr, or less than about 100 mTorr. In some embodiments the chamber pressure may be reduced to a minimum pressure that the vacuum pump may achieve during the pump to base operation, e.g., during a 30 second period or any other period disclosed above. In some embodiments, a vacuum pump is configured to reduce pressure at a maximum rate during a pump to base operation. After a pump to base operation the process chamber pressure may be increased to various pressures described herein for performing deposition operations, e.g., a pressure of at least about 3 Torr.

### Apparatus

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems.

In some embodiments, a tool may have two, three, four, five, or even more deposition stations positioned within a single deposition chamber or tool. In some embodiments, each station may perform the same operations or different operations. Thus, for example, hydrogen (H₂) and tungsten hexafluoride (WF₆) may be introduced in alternating pulses to the surface of the semiconductor substrate at each station, using an individual gas supply system that creates a localized atmosphere at the substrate surface. The same stations may be used for boron treatment and NF₃ treatment. In some embodiments the same stations or different stations or tools may be used for subsequent ALD bulk fill.

FIG. 8 is a schematic of a process system suitable for conducting deposition processes in accordance with embodiments. The system 800 includes a transfer module 803. The transfer module 803 provides a clean, pressurized environment to minimize risk of contamination of substrates being processed as they are moved between various reactor modules. Mounted on the transfer module 803 is a multi-station reactor 809 capable of performing ALD deposition of WN and/or other metal films, treatment, and CVD according to various embodiments. Multi-station reactor 809 may include multiple stations 811, 813, 815, and 817 that may sequentially or simultaneously perform operations in accordance with disclosed embodiments. For example, multi-station reactor 809 may be configured such that station 811 performs a W sub-layer deposition using a WF₆ and B₂H₆, station 813 performs a nitridation using NH₃, station 815 performs ALD tungsten bulk deposition of a conformal layer using H₂ as reducing agent. In another example, station 811 may perform deposition of WN layer, station 813 performs ALD deposition of a conformal layer, station 815 performs a NF₃ treatment operation, and station 817 may perform a bulk ALD fill after treatment using H₂ ae reducing agent.

As noted above, in some embodiments, wafers are indexed to each of stations 811, 813, 815, and 817 prior to deposition operations described herein. As shown in FIG. 7, each station is marked with a number 1-4. The labels 1-4 may correspond with stations 1-4 in FIG. 6. Thus, during a wafer loading operation, wafer A may be placed onto station 1, and while wafer A is indexed to station 2, wafer B may be placed onto station 1. This may be repeated, indexing each wafer to the subsequent station until each station has a wafer. While the stations 811, 813, 815, and 817 have been labeled 1-4 in FIG. 8, station 811 is not necessarily station 1 and other methods of indexing wafers onto stations may be used.

Stations may include a heated pedestal or substrate support, one or more gas inlets or showerhead or dispersion plate.

One or more single or multi-station modules 807 capable of performing plasma or chemical (non-plasma) pre-cleans, other deposition operations, or etch operations may be mounted on the transfer module 803. The module may also be used for various treatments to, for example, prepare a substrate for a deposition process. The system 800 also includes one or more wafer source modules 801, where wafers are stored before and after processing. An atmospheric robot (not shown) in the atmospheric transfer chamber 819 may first remove wafers from the source modules 801 to loadlocks 821. A wafer transfer device (generally a robot arm unit) in the transfer module 803 moves the wafers from loadlocks 821 to and among the modules mounted on the transfer module 803.

In various embodiments, a system controller 829 is employed to control process conditions during deposition. The controller 829 will typically include one or more memory devices and one or more processors. A processor may include a CPU or computer, analog and/or digital input/output connections, stepper motor controller boards, etc.

The controller 829 may control all of the activities of the deposition apparatus. The system controller 829 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 829 may be employed in some embodiments.

Typically, there will be a user interface associated with the controller 829. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 829. The signals for controlling the process are output on the analog and digital output connections of the deposition apparatus 800.

The system software may be designed or configured in many different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 829 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 829, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 829, in some implementations, may be a part of or coupled to a computer that is integrated with, coupled to the system, otherwise networked to the system, or a combination thereof. For example, the controller 829 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. As described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 829 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

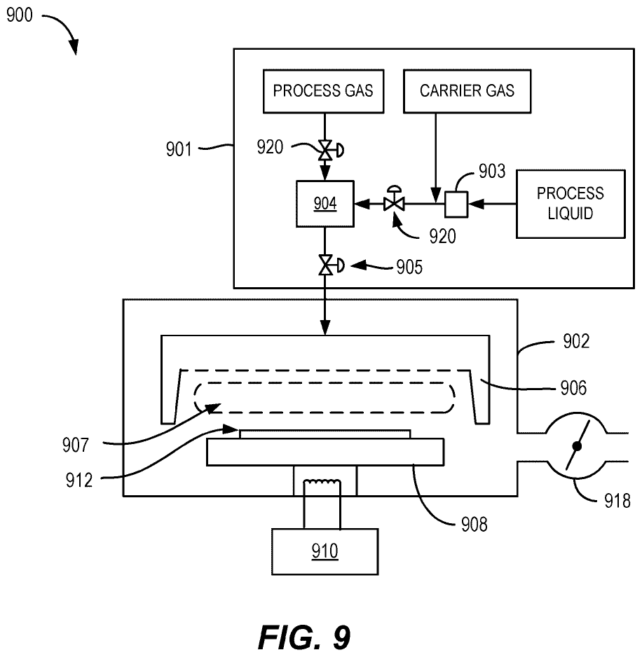

FIG. 9 schematically shows an embodiment of a process station 900 that may be used to deposit material using atomic layer deposition (ALD) and/or chemical vapor deposition (CVD). For simplicity, the process station 900 is depicted as a standalone process station having a process chamber body 902 for maintaining a low-pressure environment. However, it will be appreciated that a plurality of process stations 900 may be included in a common process tool environment. Further, it will be appreciated that, in some embodiments, one or more hardware parameters of process station 900, including those discussed in detail below, may be adjusted programmatically by one or more computer controllers.

Process station 900 fluidly communicates with reactant delivery system 901 for delivering process gases to a distribution showerhead 906. Reactant delivery system 901 includes a mixing vessel 904 for blending and/or conditioning process gases for delivery to showerhead 906. One or more mixing vessel inlet valves 920 may control introduction of process gases to mixing vessel 904. Similarly, a showerhead inlet valve 905 may control introduction of process gasses to the showerhead 906.

Some reactants may be stored in liquid form prior to vaporization at and subsequent delivery to the process station. For example, the embodiment of FIG. 9 includes a vaporization point 903 for vaporizing liquid reactant to be supplied to mixing vessel 904. In some embodiments, vaporization point 903 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 903 may be heat traced. In some examples, mixing vessel 904 may also be heat traced. In one non-limiting example, piping downstream of vaporization point 903 has an increasing temperature profile extending from approximately 100° C. to approximately 150° C. at mixing vessel 904.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 903. In one scenario, a liquid injector may be mounted directly to mixing vessel 904. In another scenario, a liquid injector may be mounted directly to showerhead 906.

In some embodiments, a liquid flow controller upstream of vaporization point 903 may be provided for controlling a mass flow of liquid for vaporization and delivery to process station 900. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 906 distributes process gases toward substrate 912. In the embodiment shown in FIG. 9, substrate 912 is located beneath showerhead 906, and is shown resting on a pedestal 908. It will be appreciated that showerhead 906 may have any suitable shape and may have any suitable number and arrangement of ports for distributing processes gases to substrate 912.

In some embodiments, a microvolume 907 is located beneath showerhead 906. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 908 may be raised or lowered to expose substrate 912 to microvolume 907 and/or to vary a volume of microvolume 907. For example, in a substrate transfer phase, pedestal 908 may be lowered to allow substrate 912 to be loaded onto pedestal 908. During a deposition process phase, pedestal 908 may be raised to position substrate 912 within microvolume 907. In some embodiments, microvolume 907 may completely enclose substrate 912 as well as a portion of pedestal 908 to create a region of high flow impedance during a deposition process.

Optionally, pedestal 908 may be lowered and/or raised during portions the deposition process to modulate process pressure, reactant concentration, etc., within microvolume 907. In one scenario where process chamber body 902 remains at a base pressure during the deposition process, lowering pedestal 908 may allow microvolume 907 to be evacuated. Example ratios of microvolume to process chamber volume include, but are not limited to, volume ratios between 1:800 and 1:10. It will be appreciated that, in some embodiments, pedestal height may be adjusted programmatically by a suitable computer controller.

In another scenario, adjusting a height of pedestal 908 may allow a plasma density to be varied during plasma activation and/or treatment cycles included in the deposition process. At the conclusion of the deposition process phase, pedestal 908 may be lowered during another substrate transfer phase to allow removal of substrate 912 from pedestal 908.

While the example microvolume variations described herein refer to a height-adjustable pedestal, it will be appreciated that, in some embodiments, a position of showerhead 906 may be adjusted relative to pedestal 908 to vary a volume of microvolume 907. Further, it will be appreciated that a vertical position of pedestal 908 and/or showerhead 906 may be varied by any suitable mechanism within the scope of the present disclosure. In some embodiments, pedestal 908 may include a rotational axis for rotating an orientation of substrate 912. It will be appreciated that, in some embodiments, one or more of these example adjustments may be performed programmatically by one or more suitable computer controllers.

In some embodiments, pedestal 908 may be temperature controlled via heater 910. Further, in some embodiments, pressure control for deposition process station 900 may be provided by butterfly valve 918. As shown in the embodiment of FIG. 9, butterfly valve 918 throttles a vacuum provided by a downstream vacuum pump (not shown). However, in some embodiments, pressure control of process station 900 may also be adjusted by varying a flow rate of one or more gases introduced to process station 900.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
providing a 3-D structure of a partially manufactured semiconductor substrate to a chamber, the 3-D structure comprising sidewalls, a plurality of openings in the sidewalls leading to a plurality of features having a plurality of interior regions fluidically accessible through the openings;
depositing a tungsten nitride film in the plurality of features using one or more deposition cycles, each deposition cycle comprising (a)-(c):
(a) forming a tungsten sublayer by:
i) dosing diborane to the chamber and purging diborane from the chamber one or more times;
ii) after (i), dosing tungsten hexafluoride to the chamber and purging tungsten hexafluoride from the chamber multiple times;
(b) after (a), dosing diborane to the chamber and purging diborane from the chamber; and
(c) after (b), dosing a nitriding agent to the chamber to convert the tungsten sublayer to a tungsten nitride sublayer and purging the nitriding agent from the chamber.

2. The method of claim 1, wherein the nitriding agent is ammonia.

3. The method of claim 1, wherein the tungsten nitride film is deposited on an aluminum oxide film in the plurality of features.

4. The method of claim 1, wherein 2, 3, or 4 deposition cycles are used to deposit the tungsten nitride film having a thickness of 10 to 20 Å.

5. The method of claim 1, wherein each deposition cycle comprises two or more iterations of (i) before the first iteration of (ii) in the deposition cycle.

6. The method of claim 1, wherein each deposition cycle comprises at least 3 iterations of (ii).

7. (canceled)

8. The method of claim 1, wherein each deposition cycle comprises at least 5 iterations of (ii).

9. The method of claim 1, wherein each of (b) and (c) is performed only once per deposition cycle.

10. The method of claim 1, wherein the number of iterations of (ii) in each deposition cycle is greater than the number of iterations of (i).

11. The method of claim 1, wherein each dose in (i) has a duration of between 1 and 2 seconds.

12. (canceled)

13. The method of claim 11, wherein each dose in (ii) has a duration of less than 1 second.

14. The method of claim 12, wherein each purge in (ii) has a duration of between 1 and 2 seconds.

15. The method of claim 1, wherein a duration of the dose in (b) is 2 to 10 times longer than a duration of each dose in (i).

16. The method of claim 1, wherein the total volume of B₂H₆ to WF₆ in (a) is at least 2:1.

17. The method of claim 1, wherein the concentration of fluorine (F) in the tungsten nitride film is less than 1.0E21.

18. (canceled)

19. The method of claim 1, wherein the concentration of fluorine (F) in the tungsten nitride film is less than 1.0E19.

20. The method of claim 1, wherein the concentration of fluorine (F) in the tungsten nitride film is less than 5E18.

21. The method of claim 1, further comprising, after depositing the tungsten nitride film, filling the plurality of features with metal.

22. An apparatus comprising:
a process chamber comprising one or more showerheads in the process chamber to direct gases and one or more substrate supports;
a controller configured to execute machine-readable instructions for depositing a tungsten nitride film using one or more deposition cycles, each deposition cycle comprising (a)-(c):
(a) causing formation of a tungsten sublayer by:
i) causing dosing of diborane to the process chamber and purging diborane from the process chamber one or more times;
ii) after (i), causing dosing of tungsten hexafluoride to the process chamber and purging tungsten hexafluoride from the process chamber multiple times;
(b) after (a), causing dosing of diborane to the process chamber and purging diborane from the process chamber; and
(c) after (b), causing dosing of a nitriding agent to the process chamber to convert the tungsten sublayer to a tungsten nitride sublayer and purging the nitriding agent from the process chamber.

23. A method comprising:
providing a process chamber comprising a plurality of stations;
indexing each substrate of a plurality of substrates to a corresponding station of the plurality of stations;
after indexing all of the plurality of substrates to the corresponding stations, reducing pressure in the process chamber below a first pressure;
after reducing the pressure in the process chamber below the first pressure, increasing the pressure in the process chamber to a second pressure higher than the first pressure; and
after increasing the pressure to the second pressure, depositing a tungsten-containing layer on each substrate of the plurality of substrates.

24. (canceled)
